(19) United States
(12) Patent Application Publication
(10) Pub. No.: US 2026/0205060 A1
(43) Pub. Date: Jul. 16, 2026

(54) AMPLIFICATION DEVICE

(71) Applicant: SUMITOMO ELECTRIC DEVICE INNOVATIONS, INC., Yokohama-shi (JP)

(72) Inventors: Seiya TAKASHIMA, Kanagawa (JP); Andrey GREBENNIKOV, Herts (GB); Christophe CUGGE, Nijmegen (NL)

(73) Assignee: SUMITOMO ELECTRIC DEVICE INNOVATIONS, INC., Yokohama-shi (JP)

(21) Appl. No.: 19/442,550

(22) Filed: Jan. 7, 2026

(30) Foreign Application Priority Data
Jan. 10, 2025 (JP) 2025-003983

(51) Int. Cl. H03F 1/26; H10W 44/20; H10W 70/40; H10W 70/654

(52) U.S. Cl. CPC H03F 1/26; H10W 44/234; H10W 70/475; H10W 70/654

(57) ABSTRACT

An amplification device includes a transistor element, a first capacitor, and a second capacitor. The first capacitor has a first conductive pattern provided on a dielectric substrate. The first conductive pattern is electrically connected to a signal output terminal of the transistor element. The second capacitor has a second conductive pattern provided on a dielectric substrate. The second conductive pattern is electrically connected to the signal output terminal of the transistor element. A capacitance of the second capacitor is smaller than a capacitance of the first capacitor. The second conductive pattern is divided into a plurality of portions that are arranged in a first direction and are connected in parallel to each other with respect to the signal output terminal. The first capacitor and the second capacitor are arranged side by side in a second direction that intersects the first direction, with respect to the transistor element.

### CROSS REFERENCE

This application claims priority to Japanese Patent Application No. 2025-003983 filed on January 10, 2025, the entire contents of which are incorporated herein by reference.

### TECHNICAL FIELD

The present disclosure relates to an amplification device.

### BACKGROUND

Japanese Unexamined Patent Application Publication No. 2016-158217 discloses a high-frequency semiconductor device. This device includes a plurality of unit FETs, a matching circuit, and a plurality of low-frequency oscillation suppression circuits. The plurality of unit FETs are arranged in parallel. The matching circuit is formed by combining branch lines that branch one line into a plurality of lines over two or more stages. The plurality of low-frequency oscillation suppression circuits are connected to a plurality of branch lines constituting an n-th stage of the matching circuit.

U.S. Patent Application Publication No. 2004/61214 discloses a packaged high-frequency power transistor including a circuit for high-frequency bypass or output matching.

### SUMMARY

An amplification device according to an embodiment of the present disclosure includes a transistor element, a first capacitor, and a second capacitor. The transistor element is provided on a base and has a signal output terminal. The first capacitor has a dielectric substrate provided on the base, and a first conductive pattern provided on the dielectric substrate. The first conductive pattern is electrically connected to the signal output terminal. The second capacitor has a dielectric substrate provided on the base, and a second conductive pattern provided on the dielectric substrate. The second conductive pattern is electrically connected to the signal output terminal. The second capacitor has a capacitance smaller than a capacitance of the first capacitor. The second conductive pattern is divided into a plurality of portions. The plurality of portions are arranged in a first direction and are connected in parallel to each other with respect to the signal output terminal. The first capacitor and the second capacitor are arranged side by side with respect to the transistor element in a second direction that intersects the first direction, and are arranged side by side with each other in the second direction.

### BRIEF DESCRIPTION OF DRAWINGS

FIG. 1 is a plan view showing an amplification device according to an embodiment of the present disclosure.

FIG. 2 is a cross-sectional view taken along line II-II of FIG. 1.

FIG. 3 is a circuit diagram showing a circuit configuration downstream of a transistor element in the amplification device.

FIG. 4 is a diagram schematically showing a part of the amplification device.

FIG. 5 is a plan view showing an amplification device according to a first modification.

FIG. 6 is a plan view showing an amplification device according to a second modification.

FIG. 7 is a plan view showing an amplification device according to a third modification.

FIG. 8 is a plan view showing an amplification device according to a comparative example.

FIG. 9 is a circuit diagram showing a circuit configuration downstream of a transistor element in the amplification device.

### DETAILED DESCRIPTION

In a package that houses a transistor element, a transistor element extending along a certain direction, a first capacitor, and a second capacitor may be arranged side by side along a direction intersecting the direction. The first capacitor is included in, for example, a shunt circuit, and the second capacitor is included in, for example, a fundamental wave matching circuit (low-pass filter circuit). A plurality of wires extend from the transistor element toward the first capacitor and the second capacitor. In such a configuration, the first capacitor and the second capacitor also extend along the extending direction of the transistor element.

Generally, the capacitance of a capacitor of a fundamental wave matching circuit is significantly smaller than the capacitance of a capacitor of a shunt circuit. When the capacitance of the second capacitor is smaller than the capacitance of the first capacitor, if the length of the second capacitor in the extending direction is made substantially the same as the length of the first capacitor in the extending direction, the width of the second capacitor becomes too narrow, which hinders mounting work and wire connection of the second capacitor. In addition, in order not to shorten the width of the second capacitor, it is conceivable to make the dielectric constant of the constituent material of the dielectric substrate of the second capacitor lower than the dielectric constant of the dielectric substrate of the first capacitor, or to make the dielectric substrate of the second capacitor thicker than the dielectric substrate of the first capacitor. However, in those cases, a dielectric substrate different from the dielectric substrate of the first capacitor is used as the dielectric substrate of the second capacitor. Therefore, the number of types of components increases, and the manufacturing cost increases.

Furthermore, in an amplification device including a transistor element, a fundamental wave matching circuit may be connected to a signal output terminal of the transistor element. Typically, the fundamental wave matching circuit has a configuration of a T-type low-pass filter circuit. In an amplification device with a large output power, a plurality of transistors are arranged in parallel inside the transistor element. In that case, since the size of the transistor element along the arrangement direction of the plurality of transistors becomes large, a large number of wires arranged along the direction, which constitute the T-type low-pass filter circuit, are connected to the signal output terminal of the transistor element. As a result, the distance between the wires located at both ends of the wire array becomes long, and loop oscillation occurs via the electrodes of the capacitor of the T-type low-pass filter circuit. Such loop oscillation deteriorates the operating characteristics of the amplification device.

An object of the present disclosure is to provide an amplification device that does not hinder mounting work and wire connection and can avoid an increase in the number of types of components. Another object of the present disclosure is to provide an amplification device that can reduce loop oscillation.

### Description of Embodiment of the Present Disclosure

First, the contents of the embodiments of the present disclosure will be listed and described. [1] An amplification device according to an embodiment of the present disclosure includes a transistor element, a first capacitor, and a second capacitor. The transistor element is provided on a base and has a signal output terminal. The first capacitor has a dielectric substrate provided on the base, and a first conductive pattern provided on the dielectric substrate. The first conductive pattern is electrically connected to the signal output terminal. The second capacitor has a dielectric substrate provided on the base, and a second conductive pattern provided on the dielectric substrate. The second conductive pattern is electrically connected to the signal output terminal. The second capacitor has a capacitance smaller than a capacitance of the first capacitor. The second conductive pattern is divided into a plurality of portions. The plurality of portions are arranged in a first direction and are connected in parallel to each other with respect to the signal output terminal. The first capacitor and the second capacitor are arranged side by side with respect to the transistor element in a second direction that intersects the first direction, and are arranged side by side with each other in the second direction.

In the amplification device of the above [1], the second conductive pattern of the second capacitor is divided into a plurality of portions that are connected in parallel to each other with respect to the signal output terminal. In this case, the capacitance of the second capacitor can be reduced without shortening the width of the second capacitor. Therefore, the mounting work and wire connection of the second capacitor are not hindered. In addition, in order to reduce the capacitance of the second capacitor, it is not necessary to make the constituent material and thickness of the dielectric substrate of the second capacitor different from the constituent material and thickness of the dielectric substrate of the first capacitor. Therefore, an increase in the number of types of components can be avoided.

[2] In the amplification device of the above [1], the dielectric substrate of the first capacitor may be integrated with the dielectric substrate of the second capacitor. In this case, the mounting work of the second capacitor can be further facilitated.

[3] In the amplification device of the above [2], the first conductive pattern may include a portion located between the plurality of portions of the second conductive pattern. In this case, the capacitance of the first capacitor can be increased while avoiding an increase in the combined mounting area of the first capacitor and the second capacitor.

[4] In the amplification device of the above [2], the first conductive pattern may have a plurality of openings arranged in the first direction, and each of the plurality of portions of the second conductive pattern may be provided inside a respective one of the plurality of openings of the first conductive pattern. In this case, the capacitance of the first capacitor can be increased while suppressing an increase in the combined mounting area of the first capacitor and the second capacitor.

[5] In the amplification device of the above [1] to [4], the first capacitor may be included in a shunt circuit, and the second capacitor may be included in a fundamental wave matching circuit. Generally, the capacitance of the capacitor of the fundamental wave matching circuit is significantly smaller than the capacitance of the capacitor of the shunt circuit. Therefore, the configuration of the amplification device of the above [1] to [4] is extremely effective.

[6] The amplification device of the above [1] to [5] may further include a low-frequency suppression circuit. The low-frequency suppression circuit may have a resistor electrically connected to the first conductive pattern, and a third capacitor electrically connected to the resistor. In this case, an amplification device that can reduce low-frequency components included in an output signal can be provided.

[7] An amplification device according to an embodiment of the present disclosure includes a transistor element and a fundamental wave matching circuit. The transistor element has a signal output terminal. The fundamental wave matching circuit is connected to the signal output terminal. The fundamental wave matching circuit has a plurality of circuit portions connected in parallel to each other with respect to the signal output terminal. Each of the plurality of circuit portions has a first wire, a second wire, and a capacitor. The second wire is connected in series between the first wire and the signal output terminal. The capacitor is connected between a reference potential and a node between the first wire and the second wire.

In the amplification device of the above [7], the fundamental wave matching circuit has a plurality of circuit portions, and each circuit portion constitutes a T-type low-pass filter circuit. As a result, in the T-type low-pass filter circuit of each circuit portion, the number of wires is reduced, and the distance between the wires located at both ends of the wire array is shortened. Therefore, loop oscillation can be reduced.

### Details of Embodiment of the Present Disclosure

Specific examples of the present disclosure will be described below with reference to the drawings. The present disclosure is not limited to this illustration, but is indicated by the scope of the claims, and is intended to include all modifications within the meaning and scope equivalent to the scope of the claims. In the following description, the same reference numerals are given to the same elements in the description of the drawings, and redundant description is omitted.

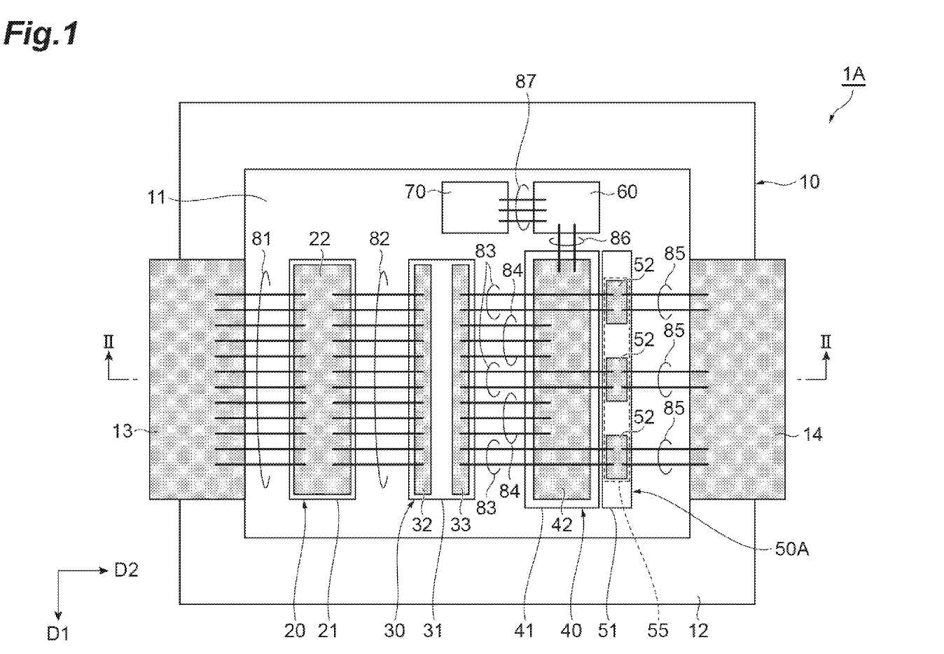

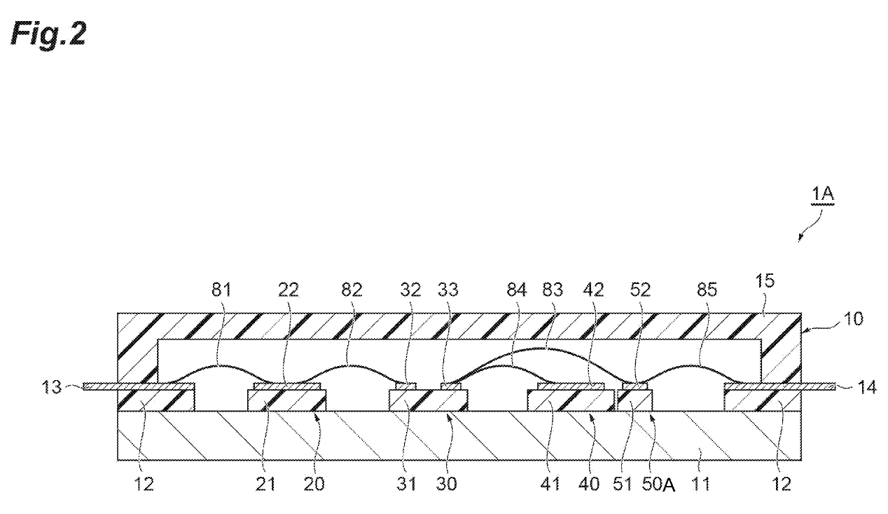

FIG. 1 is a plan view showing an amplification device 1A according to an embodiment of the present disclosure. FIG. 2 is a cross-sectional view taken along line II-II of FIG. 1. The amplification device 1A is used, for example, for one or both of a main amplifier and a peak amplifier of a Doherty amplifier. As shown in FIGS. 1 and 2, the amplification device 1A includes a package 10, a capacitor 20, a transistor element 30, a capacitor 40 (first capacitor), a capacitor 50A (second capacitor), a resistor 60, a capacitor 70 (third capacitor), and wire groups 81 to 87.

The package 10 has a base 11, a side wall 12, an input terminal 13, an output terminal 14, and a lid 15. The base 11 is a conductive plate-like member having a flat mounting surface. The mounting surface of the base 11 is made of, for example, metal only. The planar shape of the base 11 as viewed from the thickness direction of the base 11 is, for example, a rectangular shape. The base 11 is connected to an external reference potential line and set to a reference potential. FIG. 1 shows a first direction D1 along the mounting surface of the base 11 and a second direction D2 intersecting the first direction D1. In one example, the second direction D2 is orthogonal to the first direction D1. The side wall 12 has a rectangular frame shape and is disposed on the mounting surface at a peripheral portion of the base 11. The side wall 12 has insulating properties and is made of a dielectric material only. The constituent material of the side wall 12 is, for example, ceramic.

The input terminal 13 is provided on a portion along one of four sides of the side wall 12. The output terminal 14 is provided on a portion along a side opposite to the side on which the input terminal 13 is provided, among the four sides of the side wall 12. The input terminal 13 and the output terminal 14 are, for example, metal plates. A high-frequency signal before amplification is input to the input terminal 13 from an external circuit of the amplification device 1A. A high-frequency signal after amplification is output from the output terminal 14 to the external circuit of the amplification device 1A. The lid 15 is shown only in FIG. 2, and is omitted from illustration in FIG. 1. The lid 15 is a lid portion provided on the side wall 12, covers each component arranged inside the package 10, and seals the inside of the package 10. The lid 15 has insulating properties and is made of a dielectric material only. The constituent material of the lid 15 is, for example, ceramic.

The capacitor 20 is disposed inside the package 10. The capacitor 20 is disposed on the mounting surface of the base 11 at a position near the input terminal 13. The capacitor 20 is located in the second direction D2 as viewed from the input terminal 13. The capacitor 20 has a dielectric substrate 21 and a conductive pattern 22. A back surface of the dielectric substrate 21 is fixed to the mounting surface of the base 11. The conductive pattern 22 is provided on a surface of the dielectric substrate 21. The capacitor 20 extends along the first direction D1. In other words, the planar shape of the capacitor 20 is a rectangle that is long in the first direction D1. The conductive pattern 22 also extends along the first direction D1. The conductive pattern 22 is electrically connected to the input terminal 13 by a wire group 81 including a plurality of wires. The conductive pattern 22 is electrically connected to a signal input terminal 32 of a transistor element 30, which will be described later, by a wire group 82 including a plurality of wires. The inductance of the wire group 81, the capacitance of the capacitor 20, and the inductance of the wire group 82 constitute an input-side fundamental wave matching circuit (T-type low-pass filter circuit).

The transistor element 30 is disposed inside the package 10. The transistor element 30 is disposed on the mounting surface of the base 11 at a position sandwiching the capacitor 20 with the input terminal 13. In other words, the transistor element 30 is located in the second direction D2 as viewed from the capacitor 20. The transistor element 30 has a substrate 31, a signal input terminal 32, and a signal output terminal 33. The substrate 31 extends along the first direction D1, and its back surface is fixed to the mounting surface of the base 11. Inside the substrate 31, a plurality of transistors are provided in parallel. Each transistor is, for example, a field effect transistor (FET). The signal input terminal 32 is provided on the surface of the substrate 31 near the capacitor 20 and extends along the first direction D1. The signal output terminal 33 is provided on the surface of the substrate 31 near a capacitor 40, which will be described later, and extends along the first direction D1. The signal input terminal 32 is connected to a control terminal (for example, a gate) of each transistor provided inside the substrate 31. The signal output terminal 33 is connected to a first current terminal (for example, a drain) of each transistor provided inside the substrate 31. A second current terminal (for example, a source) of each transistor provided inside the substrate 31 is connected to the base 11 via the back surface of the substrate 31.

The capacitor 40 is disposed inside the package 10. The capacitor 40 is disposed on the mounting surface of the base 11 at a position near the output terminal 14. The capacitor 40 is located in the second direction D2 as viewed from the transistor element 30. In other words, the capacitor 40 is located between the transistor element 30 and the output terminal 14 in the second direction D2. The capacitor 40 is a parallel plate capacitor configured by a dielectric substrate 41 being sandwiched between a conductive pattern 42 and the base 11. The dielectric substrate 41 is provided on the mounting surface of the base 11, and its back surface is fixed to the mounting surface of the base 11. The size of the dielectric substrate 41 in the first direction D1 is, for example, 300 μm or more and 8000 μm or less, and typically 6000 μm. The size of the dielectric substrate 41 in the second direction D2 is, for example, 200 μm or more and 3000 μm or less, and typically 1000 μm. The conductive pattern 42 is provided on the surface of the dielectric substrate 41. The capacitor 40 extends along the first direction D1. In other words, the planar shape of the capacitor 40 is a rectangle that is long in the first direction D1. The conductive pattern 42 also extends along the first direction D1. The size of the conductive pattern 42 in the first direction D1 is, for example, 200 μm or more and 7900 μm or less, and typically 5900 μm. The size of the conductive pattern 42 in the second direction D2 is, for example, 100 μm or more and 2900 μm or less, and typically 900 μm. The conductive pattern 42 is a single metal film. The conductive pattern 42 is electrically connected to the signal output terminal 33 of the transistor element 30 by one or more wire groups 84 each including a plurality of wires.

The capacitor 50A is disposed inside the package 10. The capacitor 50A is disposed on the mounting surface of the base 11 at a position near the output terminal 14. The capacitor 50A is located in the second direction D2 as viewed from the transistor element 30. In other words, the capacitor 50A is located between the transistor element 30 and the output terminal 14 in the second direction D2. The capacitor 50A is arranged side by side with the capacitor 40 in the second direction D2. The capacitor 50A is a parallel plate capacitor configured by a dielectric substrate 51 being sandwiched between a conductive pattern 55 and the base 11. The dielectric substrate 51 is provided on the mounting surface of the base 11, and its back surface is fixed to the mounting surface of the base 11. The conductive pattern 55 is provided on the surface of the dielectric substrate 51.

The dielectric substrate 51 extends along the first direction D1. In other words, the planar shape of the dielectric substrate 51 is a rectangle that is long in the first direction D1. The dielectric substrate 51 is separated from the dielectric substrate 41. The constituent material and thickness of the dielectric substrate of the capacitor 50A are the same as the constituent material and thickness of the dielectric substrate of the capacitor 40. The size of the dielectric substrate 51 in the first direction D1 is, for example, 300 μm or more and 8000 μm or less, and typically 6000 μm. The size of the dielectric substrate 51 in the second direction D2 is, for example, 200 μm or more and 1000 μm or less, and typically 300 μm.

The conductive pattern 55 is divided into a plurality of portions 52. The plurality of portions 52 are provided on a common dielectric substrate 51. Each portion 52 is a metal film. The plurality of portions 52 are arranged along the first direction D1 and are connected in parallel to each other with respect to the signal output terminal 33. In one example, the planar shape of each portion 52 is a rectangle. In another example, the planar shapes of the plurality of portions 52 are identical to each other. In another example, the areas of the plurality of portions 52 are equal to each other. An interval between the plurality of portions 52 in the first direction D1 may be shorter than a length of each portion 52 in the same direction. The length of each portion 52 in the first direction D1 may be longer than a width of each portion 52 in the second direction D2. The size of each portion 52 in the first direction D1 is, for example, 100 μm or more and 2000 μm or less, and typically 1000 μm. The size of each portion 52 in the second direction D2 is, for example, 100 μm or more and 900 μm or less, and typically 200 μm.

The capacitor 50A has a capacitance smaller than the capacitance of the capacitor 40. The capacitance of the capacitor 50A referred to here is a combined capacitance between the plurality of portions 52 and the base 11. The capacitance between each portion 52 and the base 11 is mainly determined by the area of each portion 52, the distance between each portion 52 and the base 11 (in other words, the thickness of the dielectric substrate 51), and the dielectric constant of the dielectric substrate 51.

Each portion 52 of the conductive pattern 55 is electrically connected to the signal output terminal 33 of the transistor element 30 by a wire group 83 including one or more wires. In addition, each portion 52 of the conductive pattern 55 is electrically connected to the output terminal 14 by a wire group 85 including one or more wires. Each wire of the wire group 83 and the wire group 85 extends along the second direction D2. The wire group 83 extends in parallel with the wire group 84. A plurality of wire groups 83 may be arranged alternately with a plurality of wire groups 84 in the first direction D1.

The constituent material of the dielectric substrates 21, 41, and 51 is, for example, aluminum oxide (Al₂O₃) or barium titanate (BaTiO₃). The constituent material of the conductive patterns 22, 42, and 55 is, for example, gold, titanium, or copper. The constituent material of each bonding wire constituting the wire groups 81 to 85 is, for example, gold, silver, copper, or aluminum.

The resistor 60 and the capacitor 70 are disposed inside the package 10. The resistor 60 is disposed on the mounting surface of the base 11 in a direction intersecting the second direction D2 as viewed from the capacitor 40. The resistor 60 is electrically connected to the conductive pattern 42 of the capacitor 40 by a wire group 86 including one or more wires. The capacitor 70 is disposed on the mounting surface of the base 11 side by side with the resistor 60. The capacitor 70 is electrically connected to the resistor 60 by a wire group 87 including one or more wires. That is, the capacitor 70 is electrically connected to the conductive pattern 42 via the resistor 60.

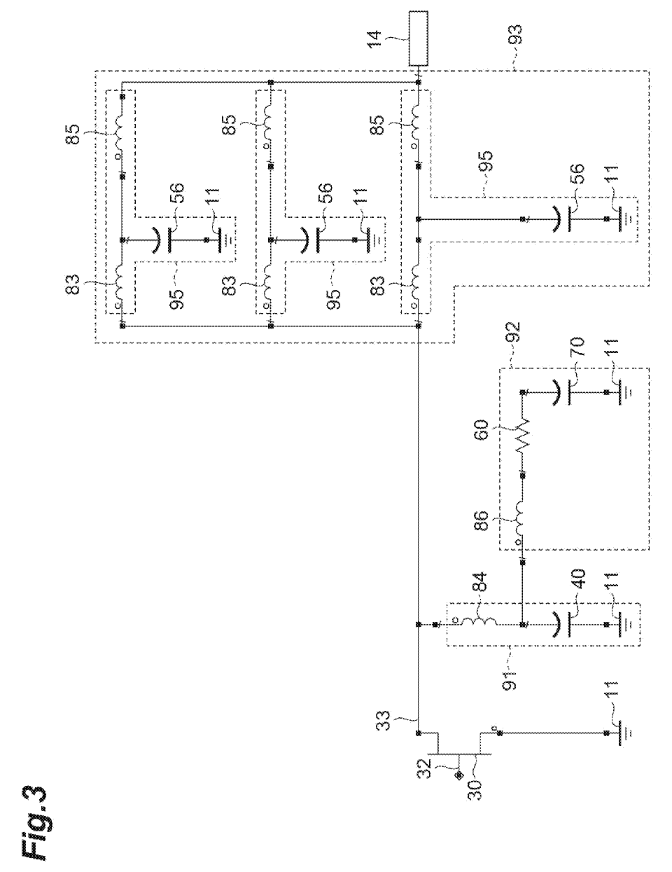

FIG. 3 is a circuit diagram showing a circuit configuration downstream of the transistor element 30 in the amplification device 1A according to the present embodiment. As shown in FIG. 3, the amplification device 1A includes a shunt circuit 91, a low-frequency suppression circuit 92, and a fundamental wave matching circuit (T-type low-pass filter circuit) 93, which are connected to the signal output terminal 33 of the transistor element 30. The shunt circuit 91 includes the aforementioned wire group 84 as an inductor and the capacitor 40, and short-circuits high-frequency components. The low-frequency suppression circuit 92 is also referred to as a video bandwidth (VBW) circuit. The low-frequency suppression circuit 92 short-circuits low-frequency components. The frequency range of the low-frequency components is, for example, 50 MHz or more and 800 MHz or less. The low-frequency suppression circuit 92 includes the aforementioned wire group 86 as an inductor, the resistor 60, and the capacitor 70. The fundamental wave matching circuit 93 adjusts the output impedance of a fundamental wave. The fundamental wave matching circuit 93 is formed by connecting a plurality of circuit portions 95 including a T-type low-pass filter circuit in parallel to each other. Each circuit portion 95 includes the aforementioned wire group 83 (second wire) as an inductor, a capacitor 56 by each portion 52 of the conductive pattern 55, and a wire group 85 (first wire) as an inductor. The capacitance of the capacitor 50A is a combined capacitance of the plurality of capacitors 56. The capacitor 56 is connected between a reference potential (base 11) and a node between the wire group 83 and the wire group 85.

The capacitance of the capacitor 40 constituting the shunt circuit 91 is set to a large value such as 100 pF, for example, in order to sufficiently short-circuit a high-frequency signal. In contrast, the capacitance of the capacitor 50A constituting the fundamental wave matching circuit 93 is set to a small value such as 15 pF, for example, from the relationship of impedance. That is, the capacitance of the capacitor 40 is significantly larger than the capacitance of the capacitor 50A. A ratio (C1/C3) between the capacitance C1 of the capacitor 40 and the capacitance C3 of the capacitor 50A is, for example, 5 or more.

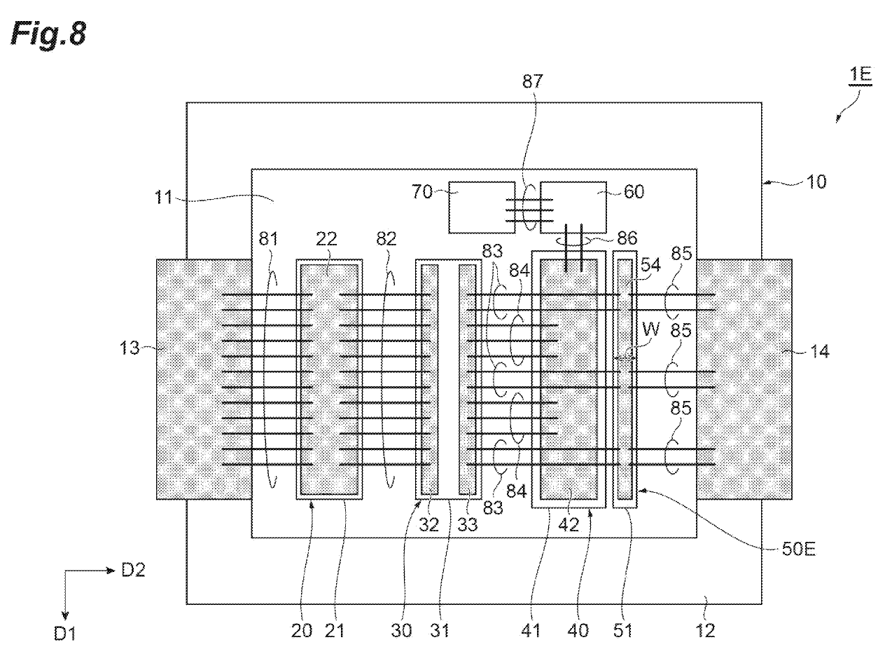

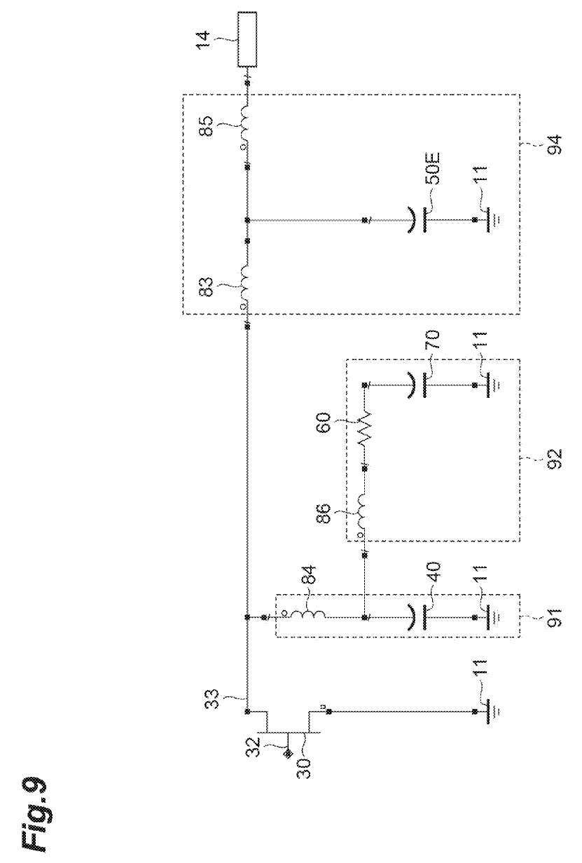

The effects obtained by the amplification device 1A of the present embodiment described above will be described together with the problems of a comparative example. FIG. 8 is a plan view showing an amplification device 1E according to a comparative example. FIG. 9 is a circuit diagram showing a circuit configuration downstream of the transistor element 30 in the amplification device 1E. The amplification device 1E is different from the amplification device 1A in that it includes a capacitor 50E instead of the capacitor 50A, and is identical to the amplification device 1A in other respects.

The capacitor 50E has the same configuration as the capacitor 50A except for the configuration described next. That is, the capacitor 50E has a conductive pattern 54 instead of the conductive pattern 55. The conductive pattern 54 is not divided into a plurality of portions and is formed on the dielectric substrate 51 as a single metal film. The conductive pattern 54 extends along the first direction D1. The conductive pattern 54 is electrically connected to the signal output terminal 33 by the wire group 83 and is electrically connected to the output terminal 14 by the wire group 85. As shown in FIG. 9, a fundamental wave matching circuit 94 is configured by the inductance of the wire group 83, the capacitance of the capacitor 50E, and the inductance of the wire group 85.

Generally, the capacitance of the capacitor 50E of the fundamental wave matching circuit 94 is significantly smaller than the capacitance of the capacitor 40 of the shunt circuit 91. When the capacitance of the capacitor 50E is smaller than the capacitance of the capacitor 40, if the length of the capacitor 50E in the extending direction (first direction D1) is made substantially the same as the length of the capacitor 40 in the extending direction (first direction D1), the width W of the capacitor 50E in the second direction D2 becomes too narrow, which hinders mounting work and wire connection of the capacitor 50E. In addition, in order not to shorten the width W of the capacitor 50E, it is conceivable to make the dielectric constant of the constituent material of the dielectric substrate 51 of the capacitor 50E lower than the dielectric constant of the dielectric substrate 41 of the capacitor 40, or to make the dielectric substrate 51 of the capacitor 50E thicker than the dielectric substrate 41 of the capacitor 40. However, in those cases, a dielectric substrate different from the dielectric substrate 41 of the capacitor 40 is used as the dielectric substrate 51 of the capacitor 50E. Therefore, the number of types of components increases, and the manufacturing cost increases.

In view of the above problems, in the amplification device 1A of the present embodiment, the conductive pattern 55 of the capacitor 50A is divided into a plurality of portions 52 that are connected in parallel to each other with respect to the signal output terminal 33. In this case, the capacitance of the capacitor 50A can be reduced without shortening the width of the capacitor 50A (in other words, the width of the dielectric substrate 51). Therefore, the mounting work and wire connection of the capacitor 50A are not hindered. In addition, in order to reduce the capacitance of the capacitor 50A, it is not necessary to make the constituent material and thickness of the dielectric substrate 51 different from the constituent material and thickness of the dielectric substrate 41 of the capacitor 40. Therefore, an increase in the number of types of components can be avoided.

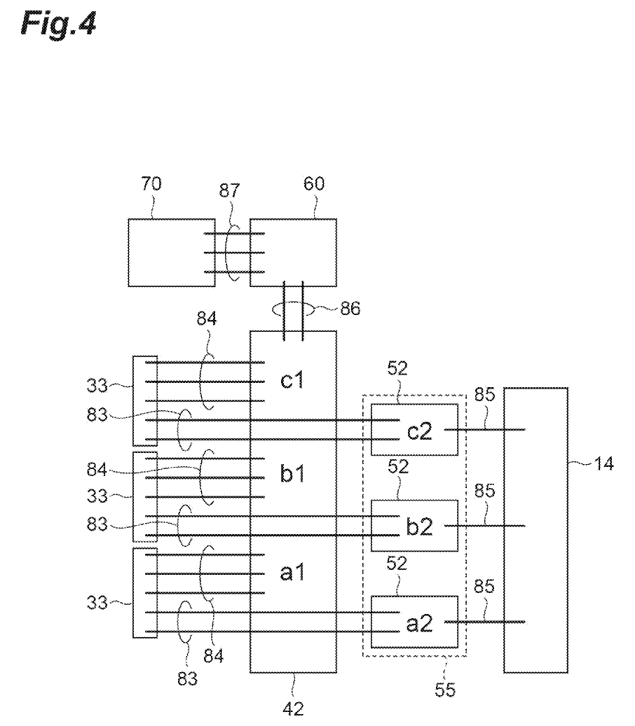

It will be explained that dividing the conductive pattern 55 into the plurality of portions 52 does not affect the operation of the amplification device 1A. FIG. 4 is a diagram schematically showing a part of the amplification device 1A. As shown in FIG. 4, regions where the three wire groups 84 are respectively connected in the conductive pattern 42 and regions in the vicinity thereof are considered as a node a1, a node b1, and a node c1. Further, the three portions 52 of the conductive pattern 55 are considered as a node a2, a node b2, and a node c2, respectively. At this time, in the conductive pattern 42, it is necessary that both the node b1 and the node c1, and the node a1 are the same point on a low frequency signal. Therefore, the node a1, the node b1, and the node c1 need to exist on the same metal film. In contrast, the conductive pattern 55 exhibits the same function as when three parallel circuits are not separated from each other, even if the node a2, the node b2, and the node c2 are separated from each other. Therefore, there is no problem even if the conductive pattern 55 is divided into the plurality of portions 52.

In addition, by dividing the conductive pattern 55 into the plurality of portions 52, the number of wires in the wire group 85 may be smaller than that in the comparative example. However, since there is no problem in the circuit operation even if the inductance of the wire group 85 is large, the number of wires in the wire group 85 may be small.

As in the present embodiment, the capacitor 40 may be included in the shunt circuit 91, and the capacitor 50A may be included in the fundamental wave matching circuit 93. By canceling the output capacitance of the transistor element 30 by the shunt circuit 91 and providing the fundamental wave matching circuit 93 at a subsequent stage, the load impedance characteristics of the amplification device 1A can be adjusted to bring the optimum load closer to the real axis (that is, to decrease the imaginary component (reactance) of the load impedance and increase the real component (resistance component)). Generally, the capacitance of the capacitor of the fundamental wave matching circuit is significantly smaller than the capacitance of the capacitor of the shunt circuit. Therefore, the configuration of the amplification device 1A of the present embodiment is extremely effective.

As in the present embodiment, the amplification device 1A may include the low-frequency suppression circuit 92. In this case, an amplification device 1A that can reduce low-frequency components included in an output signal can be provided.

Here, the reason why the conductive pattern 42 is single (not divided into a plurality of portions) in the present embodiment will be described. In the amplification device 1A having a large output power, a plurality of transistors are placed in parallel in the transistor element 30. In that case, since the width of the transistor element 30 in the first direction D1 becomes long, it becomes impossible to regard the output nodes of all the transistors as a single node. Therefore, for example, the plurality of transistors are divided into two groups in the first direction D1, and the circuit is designed such that each transistor operates uniformly while considering the inductance and resistance existing between the two groups, in other words, such that the impedance viewed from the output node of each group becomes equal. In addition, the low-frequency suppression circuit 92 is often arranged asymmetrically with respect to the center line of the amplification device 1A for layout convenience in order to make the value of the capacitor 70 a large value such as on the order of nF.

A case where the conductive pattern 42 of the capacitor 40 is divided into a plurality of portions, that is, the nodes a1, b1, and c1 shown in FIG. 4, is considered. In that case, in the vicinity of the operating frequency, since the capacitance value of the capacitor 40 is sufficiently large, the nodes a1, b1, and c1 are substantially short-circuited with the base 11 (reference voltage), and the influence of the branch to the low-frequency suppression circuit 92 can be ignored. Therefore, the impedances of the nodes a1, b1, and c1 at the operating frequency appear to be the same as each other. On the other hand, in the vicinity of the low frequency, it is desirable that the nodes a1, b1, and c1 are connected to the low-frequency suppression circuit 92 with the shortest possible inductance. However, the nodes a1 and b1 are connected to the node c1 via wiring inside the transistor element 30 or via wiring inside the side wall 12. Therefore, the inductance between each of the nodes a1 and b1 and the low-frequency suppression circuit 92 becomes large, and the effect of the low-frequency suppression circuit 92 is reduced, which causes a memory effect during amplification of a wideband signal.

Therefore, in the present embodiment, the conductive pattern 42 is not divided into a plurality of portions but is made single. This allows the nodes a1 and b1 to be connected to the node c1 with a small inductance. Therefore, the impedances of the nodes a1, b1, and c1 at the low frequency can also be made the same as each other. From this, even when the conductive pattern 42 is divided into a plurality of portions (nodes a1, b1, and c1), if those portions are interconnected via extremely short wires, for example, with a height of 200 μm or less and a length of 500 μm or less, the same function as when the conductive pattern 42 is single can be performed.

In the amplification device 1A of the present embodiment, the fundamental wave matching circuit 93 has a plurality of circuit portions 95, and each circuit portion 95 constitutes a T-type low-pass filter circuit. As a result, in the T-type low-pass filter circuit of each circuit portion 95, the number of wires is reduced. Specifically, in the comparative example of FIG. 8, three wire groups 83 are connected to the conductive pattern 54, but in the present embodiment, only one wire group 83 is connected to each portion 52 of the conductive pattern 55. This shortens the distance between the wires located at both ends of the wire array. Therefore, loop oscillation can be reduced.

### First Modification

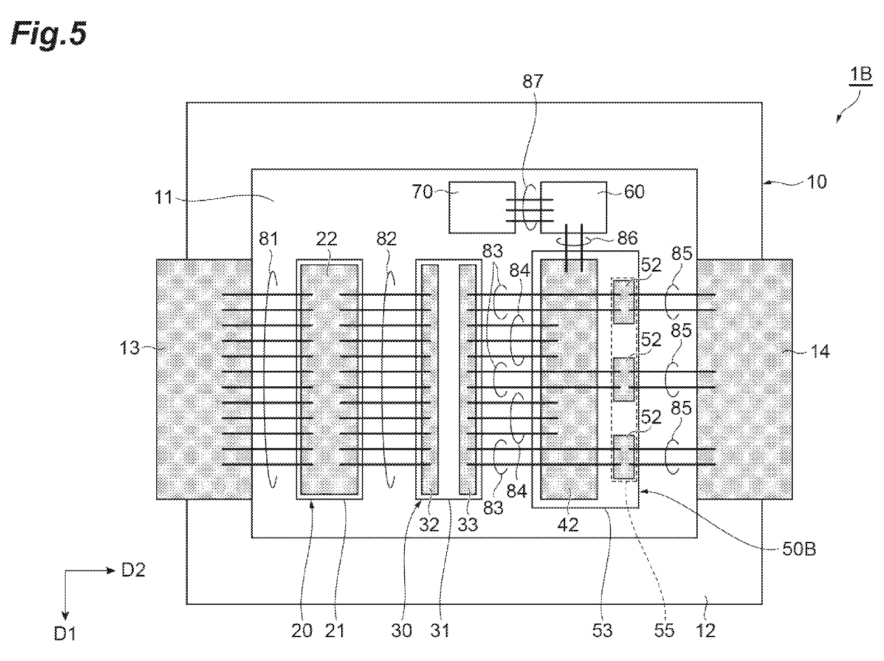

FIG. 5 is a plan view showing an amplification device 1B according to a first modification. The amplification device 1B is different from the amplification device 1A of the above embodiment in that it includes a capacitor 50B instead of the capacitors 40 and 50A, and is identical to the amplification device 1A in other respects.

The capacitor 50B is disposed inside the package 10. The capacitor 50B is disposed on the mounting surface of the base 11 at a position near the output terminal 14. The capacitor 50B is located in the second direction D2 as viewed from the transistor element 30. In other words, the capacitor 50B is located between the transistor element 30 and the output terminal 14 in the second direction D2.

The capacitor 50B has a dielectric substrate 53, a conductive pattern 42, and a conductive pattern 55. The dielectric substrate 53 is provided on the mounting surface of the base 11, and its back surface is fixed to the mounting surface of the base 11. The dielectric substrate 53 extends along the first direction D1. In other words, the planar shape of the dielectric substrate 53 is a rectangle that is long in the first direction D1. The thickness and material of the dielectric substrate 53 are the same as those of the dielectric substrates 41 and 51 of the above embodiment. The size of the dielectric substrate 53 in the first direction D1 is, for example, 300 μm or more and 8000 μm or less, and typically 6000 μm. The size of the dielectric substrate 53 in the second direction D2 is, for example, 700 μm or more and 3000 μm or less, and typically 800 μm. The conductive patterns 42 and 55 are provided on the surface of the dielectric substrate 53. The configuration, shape, material, and connection relationship of the conductive patterns 42 and 55 are the same as those in the above embodiment.

In this modification, the conductive pattern 42 and the conductive pattern 55 are provided on a common dielectric substrate 53. In other words, the dielectric substrate of the capacitor constituting the shunt circuit is integrated with the dielectric substrate of the capacitor constituting the fundamental wave matching circuit. In this case, since the width of the dielectric substrate can be further increased, the mounting work of the capacitor can be further facilitated.

### Second Modification

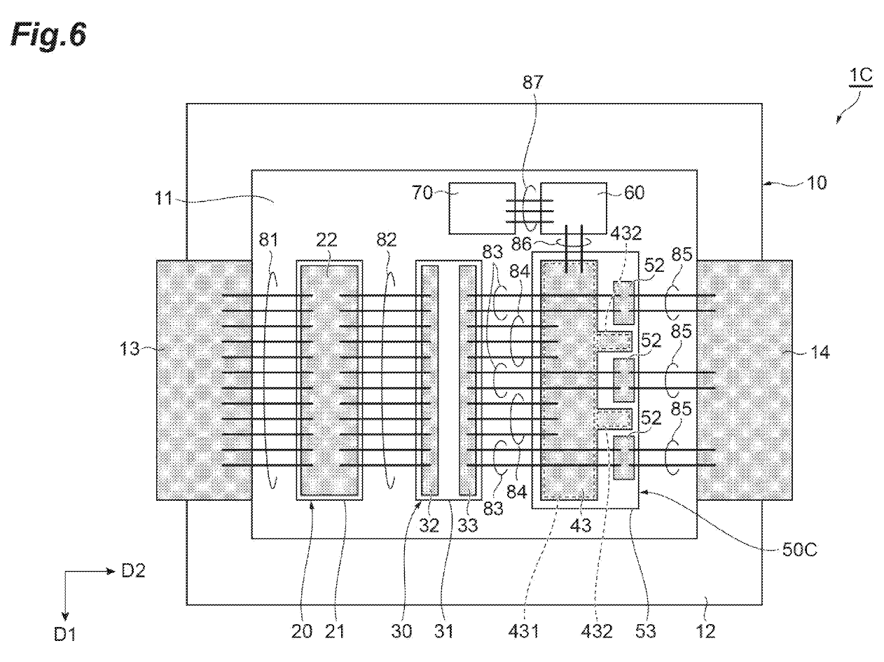

FIG. 6 is a plan view showing an amplification device 1C according to a second modification. The amplification device 1C is different from the amplification device 1A of the above embodiment in that it includes a capacitor 50C instead of the capacitors 40 and 50A, and is identical to the amplification device 1A in other respects.

The capacitor 50C has the same configuration as the capacitor 50B of the first modification except for the configuration described next. That is, the capacitor 50C has a conductive pattern 43 instead of the conductive pattern 42. The conductive pattern 43 includes a main portion 431 and one or more protruding portions 432. The main portion 431 has the same arrangement and the same planar shape as the aforementioned conductive pattern 42. Each protruding portion 432 protrudes from the main portion 431 along the second direction D2 and is located between the plurality of portions 52 of the conductive pattern 55. That is, the protruding portions 432 and the plurality of portions 52 are arranged alternately in the first direction D1.

As in this modification, the conductive pattern 43 may include one or more protruding portions 432 located between the plurality of portions 52 of the conductive pattern 55. In this case, the capacitance of the capacitor of the shunt circuit can be increased while avoiding an increase in the combined mounting area of the capacitor of the shunt circuit and the capacitor of the fundamental wave matching circuit.

### Third Modification

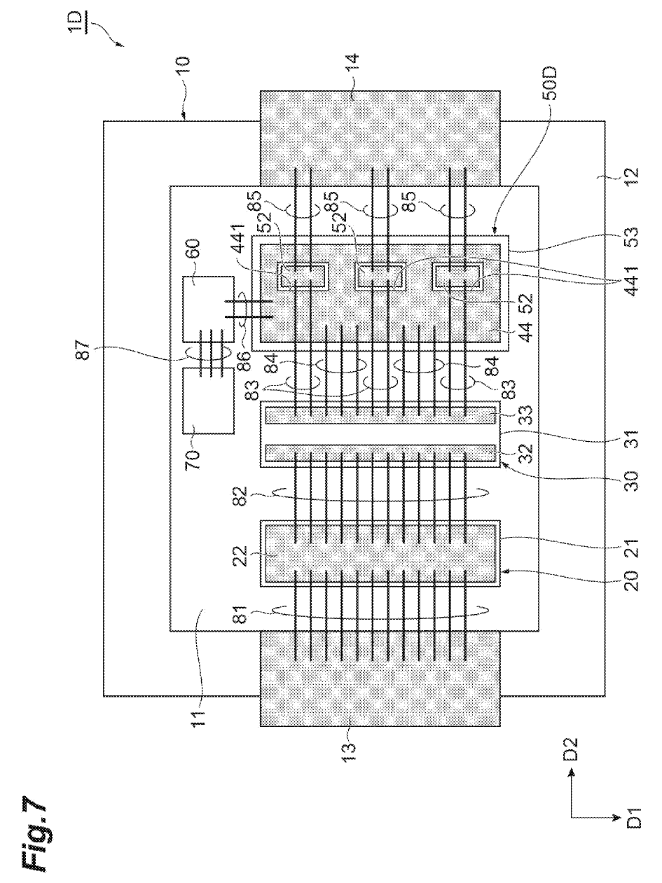

FIG. 7 is a plan view showing an amplification device 1D according to a third modification. The amplification device 1D is different from the amplification device 1A of the above embodiment in that it includes a capacitor 50D instead of the capacitors 40 and 50A, and is identical to the amplification device 1A in other respects.

The capacitor 50D has the same configuration as the capacitor 50B of the first modification except for the configuration described next. That is, the capacitor 50D has a conductive pattern 44 instead of the conductive pattern 42. The conductive pattern 44 extends on the dielectric substrate 53 over both sides of the plurality of portions 52 of the conductive pattern 55 in the second direction D2. The size of the conductive pattern 44 in the first direction D1 is, for example, 200 μm or more and 8000 μm or less, and typically 6000 μm. The size of the conductive pattern 44 in the second direction D2 is, for example, 300 μm or more and 3000 μm or less, and typically 600 μm. In addition, the conductive pattern 44 has a plurality of openings 441 arranged in the first direction D1. The planar shape of each opening 441 is, for example, a similar shape to each portion 52. Each of the plurality of portions 52 is provided inside a respective one of the plurality of openings 441 of the conductive pattern 44. This form can also be said to be that the conductive pattern 44 includes one or more portions located between the plurality of portions 52. The size of each opening 441 in the first direction D1 is, for example, 100 μm or more and 2000 μm or less, and typically 1000 μm. The size of each opening 441 in the second direction D2 is, for example, 200 μm or more and 1000 μm or less, and typically 300 μm.

According to this modification, the capacitance of the capacitor of the shunt circuit can be increased while avoiding an increase in the combined mounting area of the capacitor of the shunt circuit and the capacitor of the fundamental wave matching circuit.

The amplification device according to the present disclosure is not limited to the above-described embodiments, and various other modifications are possible. For example, in the above embodiment and each modification, an example in which the conductive pattern 55 is divided into three portions 52 is shown, but the number of divisions of the conductive pattern 55 may be two, or may be four or more. In addition, in the above embodiment and each modification, an example is shown in which the conductive pattern 42 (or the main portion 431 of the conductive pattern 43) is disposed between the conductive pattern 55 and the transistor element 30, but the conductive pattern 55 may be disposed between the conductive pattern 42 (or the main portion 431 of the conductive pattern 43) and the transistor element 30.

What is claimed is:

1. An amplification device, comprising:
a transistor element provided on a base and having a signal output terminal;
a first capacitor having a dielectric substrate provided on the base and a first conductive pattern provided on the dielectric substrate, the first conductive pattern being electrically connected to the signal output terminal; and
a second capacitor having a dielectric substrate provided on the base and a second conductive pattern provided on the dielectric substrate, the second conductive pattern being electrically connected to the signal output terminal and having a capacitance smaller than a capacitance of the first capacitor,
wherein the second conductive pattern is divided into a plurality of portions that are arranged in a first direction and are connected in parallel to each other with respect to the signal output terminal, and
the first capacitor and the second capacitor are arranged side by side with respect to the transistor element in a second direction that intersects the first direction, and are arranged side by side with each other in the second direction.

2. The amplification device according to claim 1, wherein
the dielectric substrate of the first capacitor is integrated with the dielectric substrate of the second capacitor.

3. The amplification device according to claim 2, wherein
the first conductive pattern includes a portion located between the plurality of portions of the second conductive pattern.

4. The amplification device according to claim 2, wherein
the first conductive pattern has a plurality of openings arranged in the first direction, and
each of the plurality of portions of the second conductive pattern is provided inside a respective one of the plurality of openings of the first conductive pattern.

5. The amplification device according to claim 1, wherein
the first capacitor is included in a shunt circuit, and
the second capacitor is included in a fundamental wave matching circuit.

6. The amplification device according to claim 1, further comprising a low-frequency suppression circuit,
wherein the low-frequency suppression circuit has:
a resistor electrically connected to the first conductive pattern; and
a third capacitor electrically connected to the resistor.

7. An amplification device, comprising:
a transistor element having a signal output terminal; and
a fundamental wave matching circuit connected to the signal output terminal,
wherein the fundamental wave matching circuit has a plurality of circuit portions connected in parallel to each other with respect to the signal output terminal, and
each of the plurality of circuit portions has:
a first wire;
a second wire connected in series between the first wire and the signal output terminal; and
a capacitor connected between a reference potential and a node between the first wire and the second wire.
